(19) United States
(12) Patent Application Publication
(10) Pub. No.: US 2006/0077493 A1
(43) Pub. Date: Apr. 13, 2006

(54) Apparatus and method for processing photographic image

(76) Inventors: Koji Kita, Naga-gun (JP); Noriyuki Nishi, Naga-gun (JP); Nobuki Yamada, Wakayama-shi (JP)

Correspondence Address: Norman Hanson;FULBRIGHT & JAWORSKI L.L.P., 666 Fifth Avenue, New York, NY, 10103, US

(21) Appl. No.: 11/245,759

(22) Filed: Oct. 7, 2005

(30) Foreign Application Priority Data
Oct. 8, 2004 (JP) 2004-296115

(51) Int. Cl. G03F 3/10; H04N 1/46

(52) U.S. Cl. 358/527; 358/537

(57) ABSTRACT

There is disclosed a photographic image processing apparatus for effecting image processing on inputted photographic image data though a plurality of image correcting modules and generating print data for outputting a photographic print. The apparatus includes a pre-judge screen making section for making a pre-judge screen for displaying the plurality of photographic images one after another, a photographic image selecting section for selecting a particular photographic image from the photographic images displayed on the pre-judge screen, a photographic scene allocating section for allocating a photographic scene to each selected photographic image, and an image correction module setting section for setting at least one of the plurality of image correcting modules to be used for the photographic scene allocated by the photographic scene allocating section.

### RELATED APPLICATION

This application claims priority from JP 2004-296115 filed Oct. 8, 2004, herein incorporated by reference in its entirety.

### FIELD OF THE INVENTION

The present invention relates to a photographic image processing apparatus and method for effecting image processing on inputted photographic image data though a plurality of image correcting modules and generating print data for outputting a photographic print.

### DESCRIPTION OF THE RELATED ART

In recent years, in addition to digital photographic images obtained by a digital camera, photographic images recorded on a photographic film (“film” hereinafter) such as a negative film, a reversal film, etc., are also often converted into digital images. In this connection, there has been a growing popularity for a digital mini-lab (a photographic printing apparatus) capable of processing such photographic images, by controlling an optical beam emitted from an exposure head based on such digital photographic data to scan and expose a photosensitive material (e.g., print paper), thus forming an image on the material with this controlled optical beam and outputting the resultant image-bearing material as a photographic print. Such photographic printing apparatus allows a variety of image correcting operations on the digitized photographic image including gradation adjustment, color balance adjustment, color/density adjustment thereof. By appropriately effecting such image correcting operations, the apparatus can provide a photographic print of high quality. According to a conventional image processing apparatus mounted on the digital mini-lab for effecting such image corrections, the above-described image correcting operations generally require operations of adjusting keys of various individual image processing modules included in the apparatus typically such as, three color adjusting keys for C (cyan), M (magenta) and Y (yellow), a gradation adjusting key, a contrast adjusting key, a density adjusting key, a sharpness enhancing key. However, it is very difficult to know in advance what degree of adjustment of each key will result in how much and/or what change in the image. An operator needs to obtain long experience and significant expertise before he/she can effect such operations speedily and appropriately. Therefore, appropriate image correction requires a significant amount of time for inexperienced and/or non-skillful operator.

To cope with the above situation, the Japanese Patent Application “Kokai” No. 11-194866 (see paragraphs 0012-0014, FIG. 7 thereof) has proposed an improved image processing apparatus having an information displaying means for displaying information, a display controlling means for causing the information displaying means to display, together with each image, a correction contents selecting portion for allowing selection from among possible correction contents items associated with predetermined correction conditions which concern at least a color balance and a density and which are described in natural language and an image correcting means for correcting an image being displayed on the information displaying means, based on a correction condition associated with a selected correction contents item if and when such correction contents item has been selected from the correction contents selecting unit. With this image processing apparatus, it was originally expected that as the display controlling means causes the information displaying means (a display unit) to display a photographic image together with the correction contents selecting portion for allowing selection from among correction contents items associated with predetermined correction conditions, even an inexperienced or less skillful operator not converse in the technique of the color balance, density correction or the like may smoothly carry out a necessary image correcting operation. As a matter of fact, as each correction contents item needs to be selected through use of very subjective natural language such as “clearly”, “brilliantly”, “brightly”, etc., for communication with the human operator, the result of the correction tends to vary significantly for each individual operator. Hence, if a print output is obtained through correction operations by a plurality of operators, the resultant output, i.e., a photographic print, often lacks coherence.

As a solution attempting to overcome the above-described subjective ambiguity through automatic determination of each particular photographic scene, there is known, from the Japanese Patent Application “Kokai” No. 2002-247361 (paragraph 0006, FIG. 3 thereof), a further image processing apparatus having a scene discriminating means for automatically discriminating or identifying a photographic scene of inputted image data as at least backlight scene, a nocturnal scene distinct from any other scenes, a subject exposure determining means capable of determining exposure conditions for the data excluding its background data if and when the scene discriminating means has identified the scene as either a backlight scene or a nocturnal scene, and a correcting means for effecting an image correction based on the result of determination by the subject exposure determining means. However, in actuality, a photographic image has a great variety of photographic conditions, such as a site of photography, a season of photography, composition, exposure, etc. Hence, such automatic photographic scene judgment (discrimination) and appropriate correction based on the judgment are difficult or unreliable. And, the result of the automatic correction is often inferior in quality to the result of correction assisted by human operator intervention.

Then, in an attempt to alleviate the difficulty of automatic judgment of the photographic scene based on information available from a photographic image, a still another image processing apparatus is known from the Japanese Patent Application “Kokai” No. 2004-70715. According to this apparatus, if an image file inputted to the apparatus contains image processing control information, the apparatus effects an image quality adjusting operation on the image data according to an image processing mode designated by this image processing control information. On the other hand, in case the inputted image data do not contain such image processing control information, the apparatus then proceeds to refer to a photographic mode if any described in Exif information also inputted to the apparatus and then selects a particular image processing mode using the photographic mode. Further alternatively, if no photographic mode is described therein, then, the apparatus proceeds to select an image processing mode by using some other exposure condition. Namely, this image processing apparatus attempts to achieve improvement in the reliability of automatic photographic scene discrimination through utilization of a photographic mode included in such standard photographic image format as Exif, as compared with the above-described automatic photographic scene discrimination technique relying on information available from a photographic image. Notwithstanding the above, in practice, there exist many kinds of photographic scenes which make the automatic photographic scene discrimination relying on a photographic mode difficult. Consequently, the photographic print obtained from this apparatus is still inferior in quality to a print with human operator-assisted correction.

### SUMMARY OF THE INVENTION

In view of the above-described state of the art, it is a primary object of the present invention to provide a photographic image processing apparatus which allows assistance or intervention from a human operator when needed for achieving optimal image correction result, but which minimizes the amount of correction work required from the human operator.

For accomplishing the above-noted object, according to one aspect of the present invention, there is proposed a photographic image processing apparatus for effecting image processing on inputted photographic image data through a plurality of image correcting modules and generating print data for outputting a photographic print, the apparatus comprising:
a pre-judge screen making section for making a pre-judge screen for displaying the plurality of photographic images one after another;
a photographic image selecting section for selecting a particular photographic image from the photographic images displayed on the pre-judge screen;
a photographic scene allocating section for allocating a photographic scene to each selected photographic image; and
an image correction module setting section for setting at least one of the plurality of image correcting modules to be used for the photographic scene allocated by the photographic scene allocating section.

With the above-described construction, as the pre-judge screen displays inputted photographic images one after another, one of the photographic images is selected, for which a photographic scene determining photographic conditions for that photographic image is allocated. Then, an image correction module (or a plurality of modules to be used in combination in a predetermined order) set to be used for the allocated photographic scene effects an appropriate image processing on this photographic image. The term “photographic scene” here refers specifically to “backlight scene”, “shady/cloudy scene”, “nocturnal scene”, “fluorescent lamp illuminated scene”, “tungsten lamp illuminated scene”, “flash illuminated scene”, “underwater scene”, “snow scene”, etc. In the image correction module setting section, there are set in advance an image correction module as well as parameters associated therewith to be selected for each particular photographic scene from various density converting modules (kinds of image correction modules) such as “level correction”, “tone curve”, “brightness/contrast” as well as various kinds of spatial filter modules (further kinds of image correction modules) such as “contour enhancement”, “smoothing”, etc. Hence, an image processing appropriate for each photographic scene can be effected immediately. The operator needs only to allocate a photographic scene for each selected photographic image.

While the basis of the image correction module and its parameters to be used for each photographic scene may be predetermined, it would be more convenient if the degree of this image processing, i.e., the image correction, is adjustable. For this purpose, according to one preferred embodiment of the present invention, correction intensity of each set image correction module is adjustable and this correction intensity is determined at the time of the allocation of the photographic scene for the photographic image.

In order to simplify the photographic scene allocating operation by the operator, such a user interface will be advantageous as allows the operator to select a desired photographic scene from a list of photographic scenes displayed at one time on the pre-judge screen. Further, in this connection, in case e.g., the inputted photographic image is recorded in the Exif format, attribute information associated with such photographic image can contain some photographic condition information such as “with/without flash”, “backlight”, etc. Hence, it would be more convenient for the operator if the user interface is configured to display a list of only those photographic scenes which accord with such attribute information. Further, it will be even more advantageous if visibly comprehensive icons are employed in the list of photographic scenes to be selected from.

The photographic images to be displayed one after another on the pre-judge screen are typically in accordance with the order of photographic frames. And, in many cases, there exists some continuity of a common photographic scene for a plurality of photographic images continuously aligned on the screen. For this reason, according to one preferred embodiment of the present invention, a common photographic scene can be allocated for a plurality of photographic images at one time by selection of these photographic images on the pre-judge screen. This feature can contribute to increase of speed of the photographic scene allocating operation by the operator.

According to further aspects of the present invention, there are proposed a photographic image processing method for use in the above-described photographic image processing apparatus for effecting image processing on an inputted photographic image data though a plurality of image correcting modules and generating print data for outputting a photographic print, a computer program for causing a computer to execute such method, as well as a medium storing such program therein.

For instance, the photographic image processing method according to the present invention comprises the steps of:
making a pre-judge screen for displaying the plurality of photographic images one after another;
selecting a particular photographic image from the photographic images displayed on the pre-judge screen;
allocating a photographic scene to each selected photographic image; and
setting at least one of the plurality of image correcting modules to be used for the photographic scene allocated by the photographic scene allocating unit.

Further and other features and advantages of the invention will become apparent upon reading the following detailed description of the preferred embodiments thereof with reference to the accompanying drawings.

### BRIEF DESCRIPTION OF THE DRAWINGS

FIG. 1 is a schematic of a photographic printing apparatus incorporating a photographic image processing apparatus according to the present invention,

FIG. 2 is an outer appearance view showing an example of the photographic printing apparatus incorporating the photographic image processing apparatus according to the present invention,

FIG. 3 is an explanatory view of a print station constituting the photographic printing apparatus shown in FIG. 2,

FIG. 4 is a block diagram illustrating various functional blocks of a controller employed in the photographic printing apparatus shown in FIG. 2,

FIG. 5 is a block diagram illustrating various functional blocks of an image processing unit of the controller,

FIG. 6 is a screen view showing an example of a pre-judge screen,

FIG. 7 is a screen view showing an example of a photographic scene allocating screen,

FIG. 8 is a flowchart illustrating a series of processing for effecting an image correction suited to a photographic scene and outputting a photographic print, and

FIG. 9 is a flowchart illustrating a photographic scene allocating routine.

### DESCRIPTION OF THE PREFERRED EMBODIMENTS

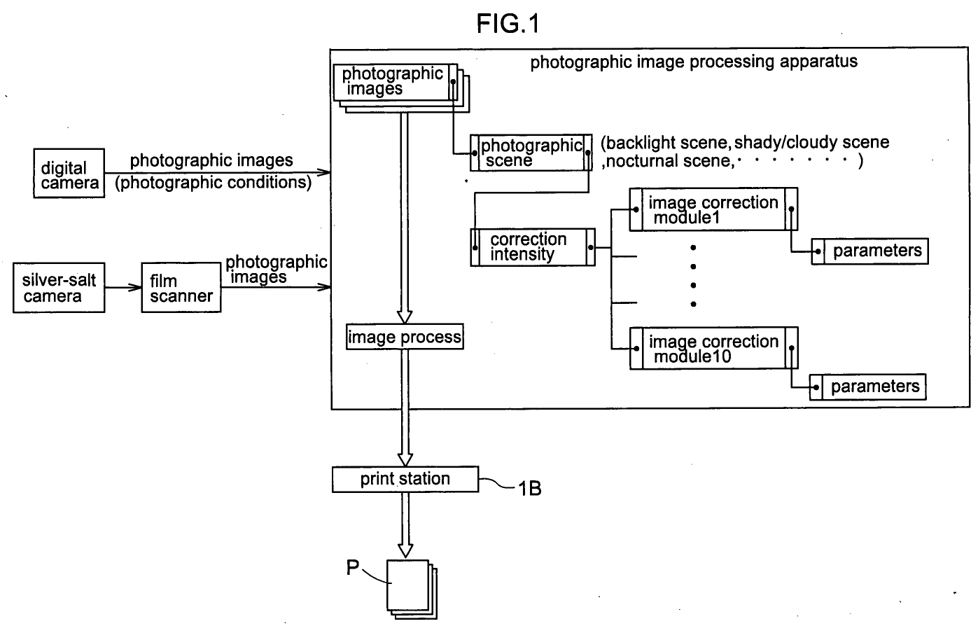

FIG. 1 is a schematic of a photographic printing apparatus incorporating a photographic image processing apparatus as a core component thereof. Photographic image data (simply “photographic image(s)” hereinafter) processed by this photographic image processing apparatus can be obtained through a digital camera or a conventional silver-salt photography camera and then inputted to the apparatus. As the apparatus processes photographic images as digital data, the image data obtained through a silver-salt camera are converted into digitized images through a film scanner in advance. Most of digital cameras currently on the market employ an image filing format known as Exif, which allows recording also of certain photographic conditions as “tag information” such as use/no-use of flash, backlight, etc. Hence, such photographic condition, if any, will be inputted to the photographic image processing apparatus together with the photographic image associated therewith. Then, the photographic image processing apparatus allows an operator to allocate a photographic scene (“backlight scene”, “shady/cloudy scene”, “nocturnal scene”, etc.) which determines the photographic condition of the inputted photographic image, and in accordance with this allocated photographic scene, there is derived an appropriate image correction (e.g., density converting operation, spatial filter operation effected by various kinds of image correction modules) to be effected on that particular photographic image. If necessary, the apparatus allows also adjustment of an intensity of the correction for the photographic image, depending on the photographic scene and/or other condition. Upon allocation of the photographic scene and correction intensity, if needed, by the operator, the apparatus then automatically sets an image correction module (s) and its (their) parameters to be used for the correction, so that with the set image correction module(s), an appropriate image processing (image correction) is effected on that photographic image. The corrected photographic image will then be transmitted to a photographic printing apparatus to be outputted as a photographic print therefrom. The essential feature of this photographic printing apparatus is that with the operator's (user's) allocation of a photographic scene to each photographic image, the apparatus then automatically effects an image correction specified for that particular photographic scene, thus outputting a photographic print with a satisfactory quality.

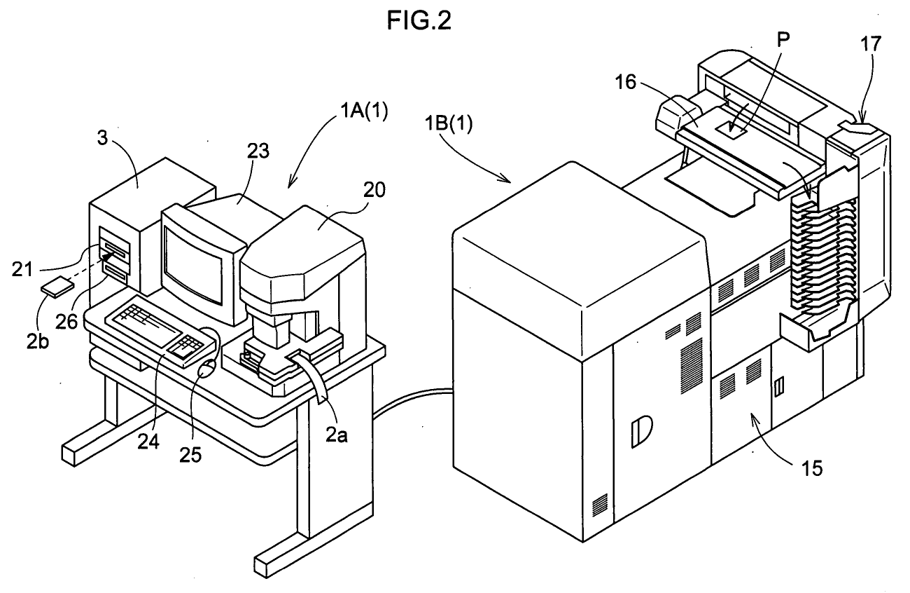

FIG. 2 shows an example of the photographic printing apparatus 1 incorporating the photographic image processing apparatus according to the present invention. This photographic printing apparatus 1 consists of a print station 1B acting as a photographic printer for effecting an exposing operation and a developing operation on a print paper P and a control station 1A for processing a photographic image inputted from an image recording medium such as a developed photographic film 2a, a memory card 2b for a digital camera, by inserting the image into an appropriate template and then forwarding the resultant synthesized image to the print station 1B.

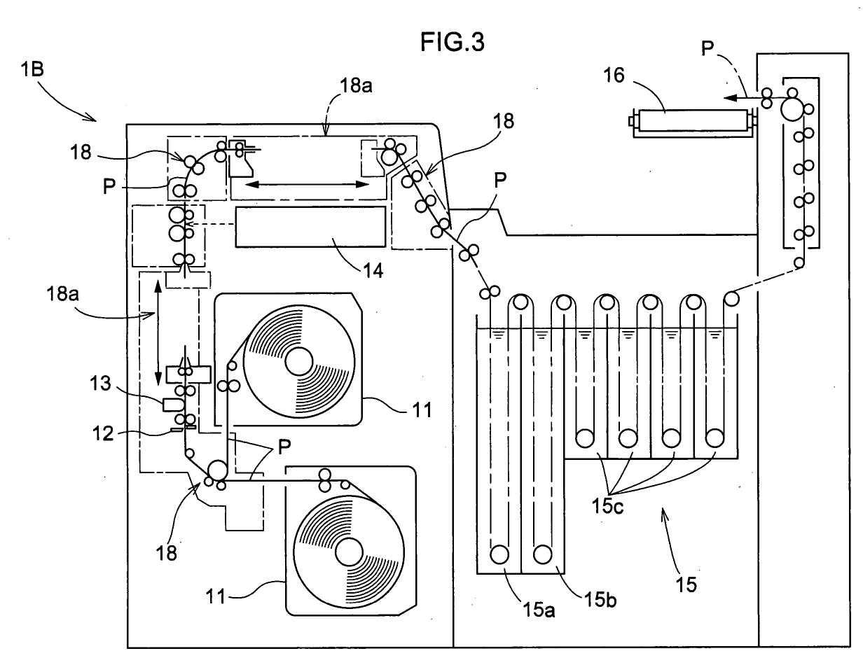

This photographic printing apparatus 1 is known also as “digital mini-lab”. As best understood from FIG. 3, in the print station 1B, a print paper P stored in the form of a roll in either one of two print paper magazines 11 is drawn out and cut by a sheet cutter 12 to a print size strip. On this print paper P (or print size strip), a back printing unit 13 prints on its back face, various print processing information, and a printing-exposing unit 14 effects an image exposure on a front face of each paper P. Then, a plurality of such exposed print papers P are charged into a developing tank unit 15 having a plurality of developing solution tanks for their development. After being dried, the developed print papers P, i.e., photographic prints or album sheets, are conveyed by a transverse conveyer 16 mounted on an upper section of the apparatus to a sorter 17, by which the prints or album sheets P are sorted according to each customer's order and stacked in a plurality of trays of the sorter 17 (see FIG. 2).

For transporting the print papers P at a speed adapted or suited for each of the above-described various operations, there is provided a print paper transporting mechanism 18. This print paper transporting mechanism 18 has a plurality of pinch transport roller pairs including chucker type print paper transport units 18a disposed before and after the print exposing unit 14 relative to the print paper transporting direction.

The print exposing unit 14 has line exposure heads for effecting irradiation of laser beams of three primary colors, R (red), G (green) and B (blue) along a main scanning direction of the print paper P which is being transported in a sub scanning direction, based on the print data sent from the operating station 1A. The developing solution tank unit 15 includes a color developing solution tank 15a which stores therein color developing solution, a bleaching/fixing solution tank 15b which stores therein bleaching/fixing solution and stabilizing solution tanks 15c which store stabilizing solutions therein.

At an upper position of a desk-like console of the operating station 1A, there is disposed a film scanner 20 for obtaining photographic image data (=a photographic image) from the respective photographically exposed frame of the photographic film 2a. Whereas, a media reader 21 for obtaining photographic images from various types of semiconductor memories, CD-R or the like used as photographic image recording media 2b mounted on a digital camera or the like is incorporated within a general-purpose personal computer which, in this embodiment, functions as a controller 3 for this photographic printing apparatus 1. The general-purpose PC is connected also to a media recording device 26 acting as an image outputting means, a monitor 23 for displaying various kinds of information and a keyboard 24 and a mouse 25 which function as operation input devices employed as an instruction inputting unit when various settings or adjustments are to be effected. Though not shown, the PC further includes connection terminals and dedicated cables for USB (Universal Serial Bus), IEEE1394 as an interface for allowing direct input of photographic images from a digital camera or the like.

In case the photographic image file inputted to this photographic printing apparatus 1 is in such a format as Exif which allows recording also of a photographic condition, this photographic condition will be inputted together with the photographic image to the apparatus, with maintaining a link relationship therebetween.

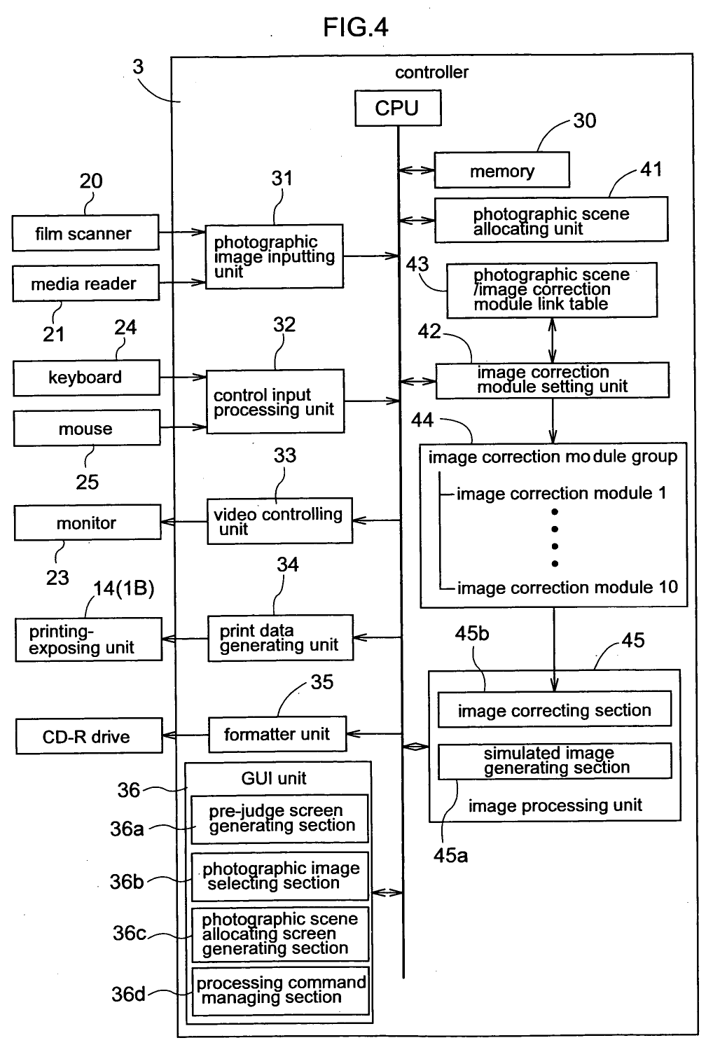

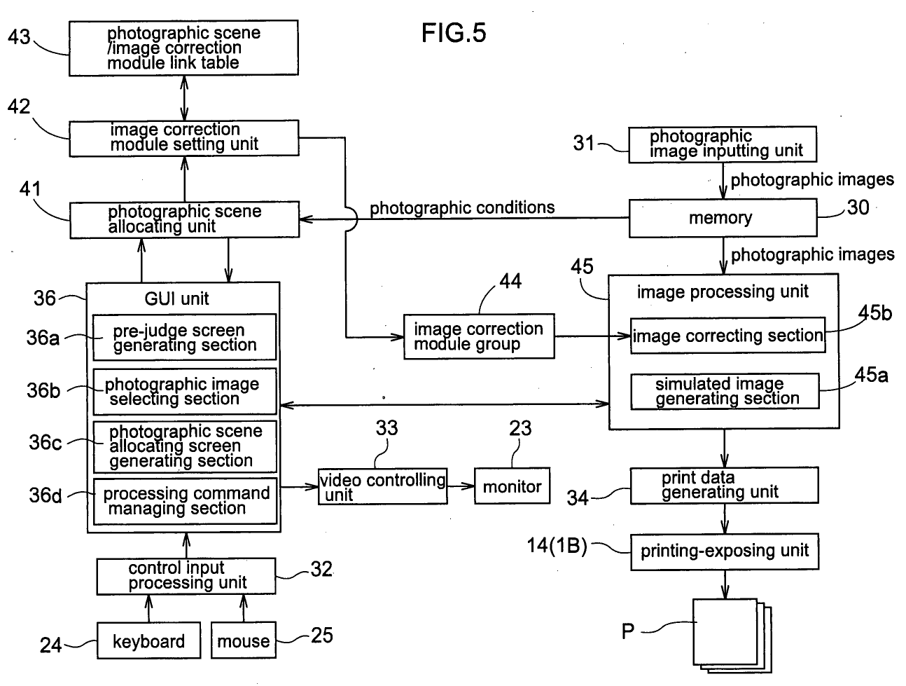

The controller 3 employed in the photographic printing apparatus 1 includes a CPU as a core component thereof and includes also various functional units or sections constructed in the form of hardware and/or software for carrying out various operations of the apparatus 1. With reference to FIGS. 4 and 5, some of input/output interface functional units thereof particularly pertinent to the technique of the invention will be described next. A photographic image inputting unit 31 effects a preprocessing required for subsequent processing on each photographic image obtained by the film scanner 20 or the media reader 21 and then maps this preprocessed image in a memory 30. An operational input processing unit 32 processes a user's operation input from the keyboard 24 or the mouse 25 to covert this into an appropriate internal processing command. A video controlling unit 33 generates video signals to be displayed eventually on a monitor 23 for displaying various kinds of image information. A print data generating unit 34 generates, from the finally processed image information, print data suitable for use in the printing-exposing unit 14 included in the print station 1B. A formatter unit 35 formats raw or edited photographic images into a format to be written into a CD or DVD in accordance with a customer's request. A GUI unit 36 constitutes a graphic user interface (“GUI” hereinafter) for making a graphically assisted control screen such as a pre-judge screen and controlling the internal processing command which has been converted from a user's operation input through such graphically assisted control screen.

Further, as operation functional units, the controller 3 further includes the following units exemplified next. A photographic scene allocating unit 41 allocates a photographic scene as instructed by the operator for each photographic image mapped in the memory 30. An image correction module setting unit 42 sets an image correction module(s) to be used for the photographic scene allocated by the photographic scene allocating unit 41, with reference to information recorded in a photographic scene/image correction module link table 43. A group of image correction modules 44 includes various image correction modules (the image correction module 1 . . . ) for effecting density converting operations, spatial filter operations, etc. An image processing unit 45 effects an image processing using the respective kind(s) of image correction modules on each photographic image mapped in the memory 30. The image processing unit 45 includes a plurality of sections including a simulated image generating section 45a for generating a simulated image which is an expected finished print image from each photographic image and an image correcting section 45b for correcting the photographic image by using the image correction module(s) set based on the photographic scene.

Referring more particularly to the functions of the photographic image inputting unit 31, in case the photographic image recording medium is a film 2a, low-resolution scanned data and high-resolution scanned data which were generated therefrom respectively at appropriately timings by a pre-scan mode operation and a main scan mode operation of the film scanner 20 will be inputted separately as image data to be subjected to a subsequent pre-processing suited for its particular purpose. In case of the photographic image recording medium being a memory card 2b, if the inputted photographic image contains thumbnail image (low-resolution data), this data will be inputted to the memory 30 separately from the main data (high-resolution data) of the photographic image to be used for, e.g., a list display on the monitor 23. On the other hand, if no thumbnail image is contained therein, a reduced image will be created from the main data and be inputted as a thumbnail image to the memory 30. Needless to say, if all operations are to be carried out in the form of high-resolution data, only high-resolution data needs to be inputted as the photographic image.

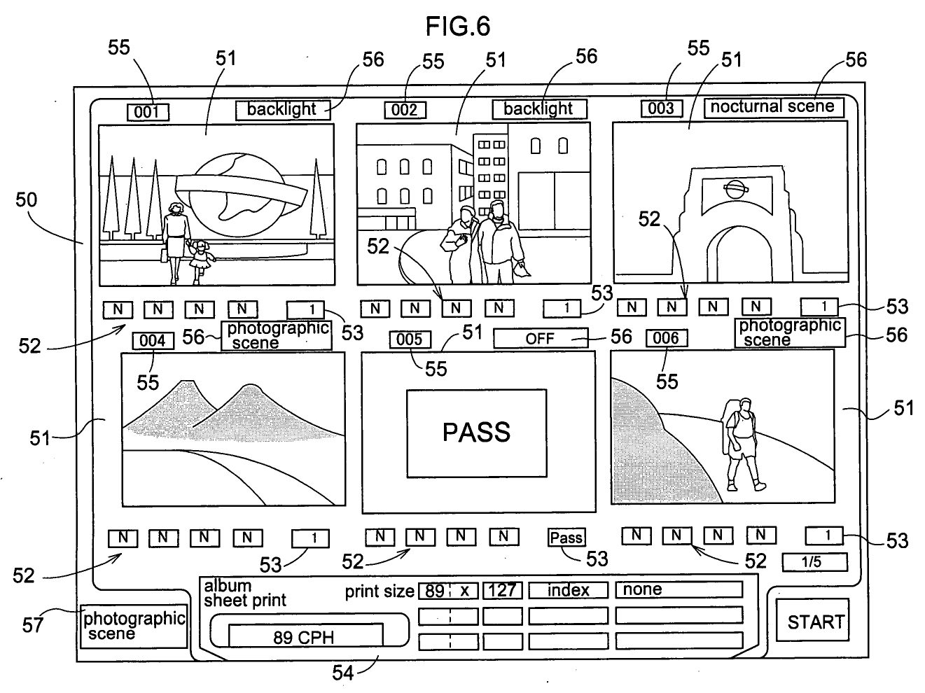

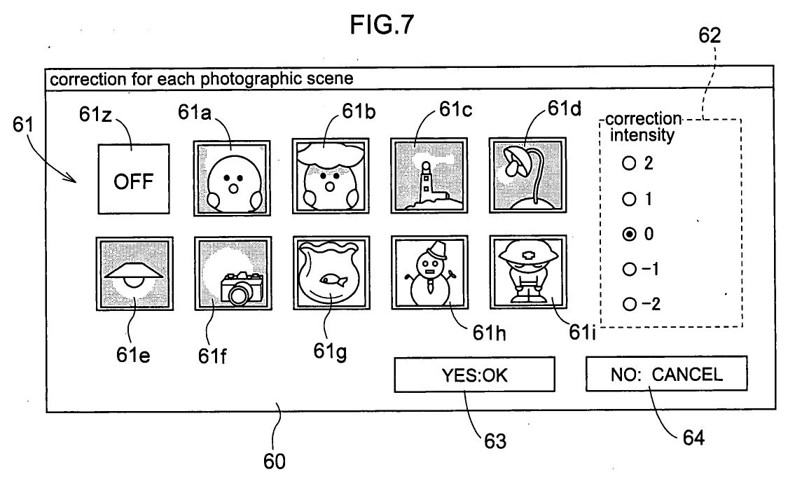

The GUI unit 36 includes a pre-judge screen making section 36a for making a pre-judge screen 50 exemplified by one shown in FIG. 6, a photographic image selecting section 36b for selecting a photographic image to be processed from the plurality of photographic images list-displayed on the pre-judge screen 50 according to an operator's instruction, a photographic scene allocating screen generating section 36c for generating a photographic scene allocating screen 60 exemplified by the one shown in FIG. 7 and a processing command managing section 36d for managing internal processing commands inputted through various control screens including the pre-judge screen 50 and the photographic scene allocating screen 60 described above.

The pre-judge screen 50 typically displays photographic images of one roll of film or one sheet of memory card one after another in respective image display frames 51 for image checking. A preset number of these image display frames 51 will be displayed. However, in the example shown in FIG. 6, there are displayed six such frames. Under each image display frame 51, there are arranged a color density correction setting area 52 and a print number setting area 53. The color density correction setting area 52 includes setting boxes of “yellow”, “magenta”, “cyan” and “density” and a correction amount “N” means neutral, i.e., no correction. The print number setting area 53 includes a print number inputting box and the language “PASS” shown in the box means no printing is to be effected on this frame image. At the lower area of the prejudge screen 50, there is provided a print condition display column 54 which shows a name of “print channel” (a predetermined set or series of print control operations) selectively applied to this particular photo print output, print sizes included in this print channel, need or no-need of index printing, need or no-need of media output, etc. The print size represents the size of a finished photographic print P. In this embodiment, the print size is determined by a width of the print paper and a feeding length of the same. Upwardly of each photographic image display frame 51, there is provided a frame ID code display column 55 for displaying a serial frame number of an image file name of the photographic image being displayed at this photographic image display frame 51.

If a color density correction of the photographic image is desired, this is possible by using a setting button provided in the color density correction setting area 52. Or, if a more detailed image correction is desired for a photographic frame, this can be facilitated by double-clicking this photographic frame to obtain a single frame enlarged display screen. However, such correction operation requires significant experience and skill on the part of the operator. If done by an inexperienced or less skillful operator, the correction can result in deterioration in the photographic quality, rather than improvement thereof. For this reason, in order to allow an appropriate image correction even by such operator, this photographic printing apparatus has a function to effect automatically an appropriate image correction, once a photographic scene has been determined for each photographic image desired to be corrected. For this purpose, on the right side of the frame ID code display column 55, there is provided a photographic scene column 56, in which a photographic scene allocated in a manner described next is displayed.

For allocating a photographic scene to a photographic image being displayed in the photographic image display frame 51, the operator will first select a desired photographic image (or desired plurality of photographic images) by clicking it (or shift-clicking them). With this, there will be “popped out” a photographic scene allocating screen 60 exemplified by the one shown in FIG. 7. This photographic scene allocating screen 60 includes, in its left area, a group of (ten) icon buttons 61 respectively representing different photographic scenes. In the right area of the screen 60, there is provided a correction intensity setting column 62 for setting a correction intensity if necessary. Numeral 63 denotes an OK button and numeral 64 denotes a cancel button, respectively.

In this embodiment, the icon button group 61 includes an OFF button 61z for instructing no correction according to any photographic scene to be effected, a “backlight” button 61a for correcting abnormality in, e.g., color balance in a backlight photography, a “shady/cloudy” button 61b for correcting abnormality in, e.g., a photography under shady/cloudy condition when a photographic image is determined as a cloudy scene photography, and further includes a “nocturnal scene” button 61c, a “fluorescent lamp” button 61d, a “tungsten lamp” button 61e, a “flash light” button 61f, a “underwater” button 61g, a “snowy” button 61h and an “industrial photography” button 61i. Incidentally, in an industrial photography, there are included characters indicative of industrial information in a mixed state. Hence, a special treatment such as a contour enhancement, will be effected.

In the photographic scene allocating image generating section 36c, for the arrangement of the icon button group 61 on the photographic scene allocating screen 60, it is advantageous if the user interface employed is configured to render transparent the icon button(s) for some photographic scene(s) which can be determined as impossible based on the photographic condition in case the Exif tag information of the selected photographic image contains such photographic condition as “with/without flash”, “backlight”, thus rendering such buttons un-selectable. Alternatively, the interface can be configured to render such buttons still selectable, but to also notify the operator in some manner that the possibility of the photographic scenes associated with such buttons is very low. Needless to say, the interface can be configured also so that the icon buttons representing such photographic scenes of low possibility are not displayed at all.

The operator will select a photographic scene which seems to match the selected photographic image and will then click the icon corresponding thereto and will also set or reset its correction intensity if necessary. The correction intensity is initially set to ‘the default value of ‘0’ (standard value). For instance, in the case of a cloudy photographic scene, if the degree of cloudiness of the target photographic image is high, then, the correction intensity can be reset to ‘1’ or ‘2’. Conversely, in the case of low degree of cloudiness, the correction intensity can be set to ‘−1’ or ‘−2’. Finally, when the operator clicks the OK button 63, this allocating information will be transmitted via the processing command managing section 36d to the photographic scene allocating unit 41, where the allocated photographic scene will be recorded in correlation with (in linked relationship with) this particular photographic image.

The photographic scene for each photographic image recorded in the processing command managing section 36d will be utilized by the image correction module setting unit 42. More particularly, with reference to the information recorded in the photographic scene/image correction module link table 43, the image correction module setting unit 42 sets an image correction module (either one module only or a plurality of modules to be used in combination) and its (their) parameters to be used for the image correction of that particular photographic image.

The information recorded in the photographic scene/image correction module link table 43 defines the selection of module(s) from the group of density converting image correction modules such as “level correction”, “tone curve”, “brightness/contrast” and the various kinds of spatial filter image correction modules such as “contour enhancement”, “smoothing”, and the parameters therefor. Such definitions are known to some extent in the art of digital photography correction. For instance, for a photographic image allocated with the “backlight scene”, the density converting module will be used for increasing the density and a contrast module will be used for enhancing the contrast. For a photographic image allocated with the “shady/cloudy scene”, a color density converting module will be used for reducing the cyan color component and the contrast module will be used for enhancing the contrast. For the other photographic scenes also, the combinations of the respective kinds of image correction modules and their parameters are defined empirically and experimentally in advance for providing appropriate image corrections respectively therefor.

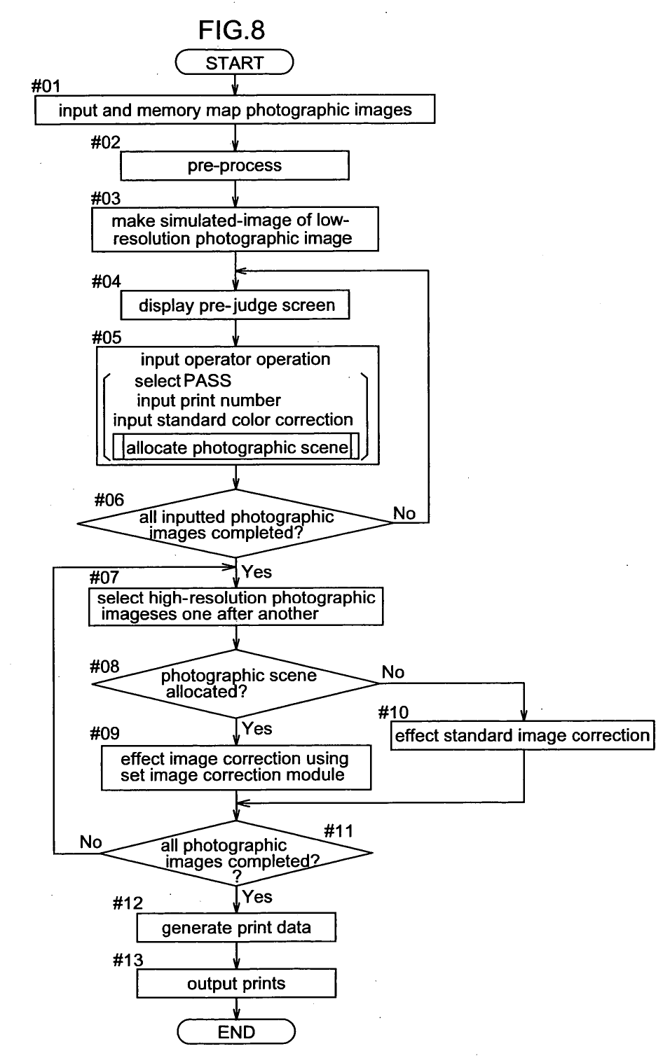

Next, with reference to the flowchart of FIG. 8, there will be described a series of operations for effecting an image correction suitable for each photographic scene and outputting a photographic print by using the photographic printing apparatus 1 having the above-described construction.

First, a photographic image file or digital image data of photographic images are inputted from the film scanner 20 or the media reader 21 via the photographic image inputting unit 31 and mapped in the memory 30 (#01). For the inputted photographic images, a pre-processing of the images is effected with using an input-device profile such as a film scanner profile or a digital camera profile (#02). The simulated image generating section 45a makes a simulated image of low-resolution photographic image (#03). Then, the pre-judge screen 50 such as the one shown in FIG. 6 made by the pre-judge screen making section 36a is displayed on the monitor 23 (#04).

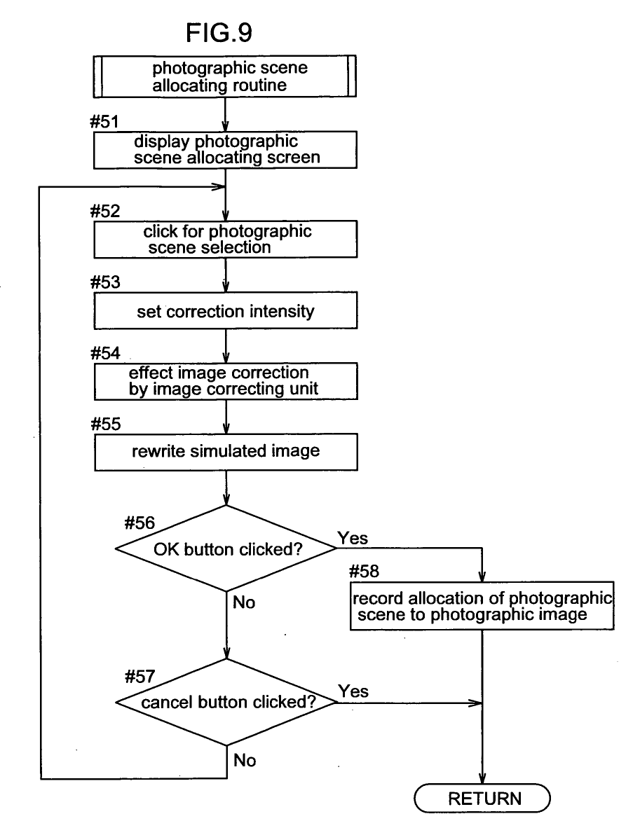

Through this pre-judge screen 50 displayed on the monitor 23, an operator can effect checking and various inputting operations for the photographic images (#05). For instance, if a defective image resulting from a failed photography is found in the list, the operator will select “PASS” in the print number setting area 53 thereof, so that this photographic image can be omitted from printing. Also, if an image having color defect is found, the operator can directly instruct a color correction by operating the various kinds of the color correction buttons provided in the color density correction setting area 52. However, if an appropriate image correction is to be effected by allocating a photographic scene to this photographic image, then, the photographic scene allocating process illustrated in FIG. 9 will be executed. These operations through the pre-judge screen 50 (i.e., “pre-judge operations”) such as the setting of a print number, the setting of a photographic scene for each photographic image will be effected for all of the inputted photographic images while renewing the pre-judge screen 50 as needed (#06).

Upon completion of the pre-judge operations, the high-resolution photographic images to be printed will be selected one after another (#07). If a photographic scene has been allocated for the selected image (YES branched at #08), an image correction with the image correction module(s) set by the image correction module setting unit 42 will be effected (#09). Conversely, in the case of absence of allocation of any photographic scene (NO branched at step #08), a standard image correction (or no correction at all) will be effected (#10). This image correction process is effected for all of the high-resolution photographic images to be printed (#11). The photographic images after the image corrections are converted into print data (#12) and then forwarded to the print station 1B (printing-exposing unit 14) and outputted as photographic prints P (#13).

Next, the photographic scene allocating process described above will be explained in details with reference to the flowchart of FIG. 9.

This photographic scene allocating routine is activated in response to clicking of the photographic scene button 57 during the inputting operations by the operator through the pre-judge screen 50. First, the photographic scene allocating screen 60 exemplified by the illustration of FIG. 7 is displayed (#51). Then, the operator will click a particular icon 61 indicative of the photographic scene agreeing with each photographic image selected on the pre-judge screen 50 (#52) and also set a correction intensity if necessary (#53). Upon allocation of a certain photographic scene, an image correction using an image correction module(s) defined by that photographic scene will be effected (#54) and a new simulated image will be produced from the image-corrected photographic image and the photographic image displayed at the photographic image display frame 51 will be rewritten (#55). With this, the operator can know clearly in advance how the photographic image allocated with the particular photographic scene will be outputted as a print. If the operator finds the simulated result of image correction satisfactory, then, the operator will click the OK button 63 (YES branched at #56) and this allocation of the photographic scene to this photographic image will be recorded in the photographic scene allocating unit 41 (#58). On the other hand, if the operator finds the result of image correction unsatisfactory, then the operator will click the cancel button (YES branched at #57) and this routine will be ended without any photographic scene allocation.

In the discussion of the foregoing embodiment, there has been described an example in which the photographic image processing apparatus of the invention is incorporated in a photographic printing apparatus called mini-lab often installed in a photo processing shop. Instead, the invention's apparatus can be incorporated in other various types of photographic printing apparatus such as a self-operated (customer-operated) photographic printing apparatus installed in a convenience shop or a photo processing shop.

In the foregoing embodiment, there is employed the so-called silver salt photographic printing technique wherein the print station 1B effects exposure of the print paper P with a photographic image at the printing-exposing unit 14 and then develops a plurality of developing operations of this exposed print paper P. Needless to say, in this invention, the print station 1B is not limited to such type. Instead, various photographic printing systems such as an ink jet printing for forming an image by jetting ink on to a film or a paper, a heat transfer printing method using a heat-sensitive sheet, etc.

1. A photographic image processing apparatus for effecting image processing on inputted photographic image data through a plurality of image correcting modules and generating print data for outputting a photographic print, the apparatus comprising:
a pre-judge screen for displaying a plurality of photographic images one after another;
a photographic image selecting section for selecting a particular photographic image from the photographic images displayed on the pre-judge screen;
a photographic scene allocating section for allocating a photographic scene to each selected photographic image; and
an image correction module setting section for setting at least one of the plurality of image correcting modules to be used for the photographic scene allocated by the photographic scene allocating section.

2. The photographic image processing apparatus according to claim 1, wherein correction intensity of each set image correction module is adjustable and this correction intensity is determined at the time of the allocation of the photographic scene for the photographic image.

3. The photographic image processing apparatus according to claim 1, wherein the allocation of the photographic scene is effected through a list of photographic scenes displayed on a pre-judge screen.

4. The photographic image processing apparatus according to claim 3, wherein said pre-judge screen is configured to display only those photographic scenes which accord with attribute information associated with the photographic images.

5. The photographic image processing apparatus according to claim 3, wherein the list of the photographic scenes on the prejudge screen comprise a group of icons indicative of the respective photographic scenes.

6. The photographic image processing apparatus according to claim 1, wherein a common photographic scene is allocated for a plurality of photographic images selected on the pre-judge screen.

7. A photographic image processing method for effecting image processing on inputted photographic image data though a plurality of image correcting modules and generating print data for outputting a photographic print, the method comprising the steps of:
displaying a plurality of photographic images one after another on a pre-judge screen;
selecting a particular photographic image from the photographic images displayed on the pre-judge screen;
allocating a photographic scene to each selected photographic image; and
setting at least one of the plurality of image correcting modules to be used for the photographic scene allocated by a photographic scene allocating unit.

8. The photographic image processing method according to claim 7, wherein a common photographic scene can be allocated for a plurality of photographic images selected on the pre-judge screen.

9. A computer-readable medium comprising computer-executable instructions for effecting image processing on inputted photographic image data though a plurality of image correcting modules and generating print data for outputting a photographic print, said instructions comprising:
displaying a plurality of photographic images one after another on a pre-judge screen;
selecting a particular photographic image from the photographic images displayed on the pre-judge screen;
allocating a photographic scene to each selected photographic image; and
setting at least one of the plurality of image correcting modules to be used for the photographic scene allocated by a photographic scene allocating unit.

10. The computer-readable medium according to claim 9, wherein a common photographic scene can be allocated for a plurality of photographic images selected on the pre-judge screen.
